(19) United States
(12) Patent Application Publication
(10) Pub. No.: US 2025/0378042 A1
(43) Pub. Date: Dec. 11, 2025

(54) SERIAL INTERFACE COMPRISING DUAL CLOCK AND DATA I/O CELL

(71) Applicant: Western Digital Technologies, Inc., San Jose, CA (US)

(72) Inventors: Thomas Schneider, Anaheim, CA (US); Kevin Matthew Colon, Mission Viejo, CA (US)

(21) Appl. No.: 18/740,053

(22) Filed: Jun. 11, 2024

(51) Int. Cl. G06F 13/42; G11C 16/32; H03K 3/037; H03K 19/0175

(52) U.S. Cl. CPC G06F 13/4282; H03K 3/037; H03K 19/017509; G06F 2213/0002; G11C 16/32

(57) ABSTRACT

A serial interface comprising an I/O cell communicates serial data from a target device to an initiator device. The I/O cell comprises a clock pad that receives a clock signal from the initiator device; a data pad that receives a data output signal from the target device; and a clock input buffer coupled to the clock pad. A flip-flop integrated in the I/O cell receives the clock signal directly from the clock input buffer, receives the data output signal from control logic of the target device, and outputs the data output signal in synchronization with the clock signal. A data output buffer receives the data output signal from the flip-flop and drives the data output signal to the data pad for access by the initiator device.

### BACKGROUND

A serial interface provides a communication pathway that enables devices to exchange data as a serial bit stream (one bit at a time). Serial interfaces are widely used in integrated circuits (ICs) and semiconductor devices to facilitate serial data communication from one IC or device (target device) to another IC or device (initiator device). For the initiator device to understand data sent from the target device, the serial interface may need to synchronize the devices, such as by using a clock signal, so that they agree when each bit of data starts and ends. In addition, the serial interface may need to ensure that data sent from the target device meets voltage level, data protocol, and other requirements of the initiator device. Essentially, the serial interface acts as a bridge for serial data communication between the two devices. In the non-limiting context of a hard disk drive (HDD), for example, a serial interface is needed between the preamplifier or PLSI (target device) that is connected to the read/write head and amplifies signals read from the disk surface, and the HDD controller (initiator device) that manages overall HDD operations and the flow of the read data.

Serial interfaces are sometimes implemented by specialized, intermediate components known as I/O (input/output) cells connecting internal signals from the core of an IC to external pins of the chip package. I/O cells manage operations such as synchronization, buffering to match speed differences between internal processes and external communication, level shifting to accommodate different voltage levels, conversion between different signaling protocols, and other requirements for serial data communication. The I/O cells may be selected from a library of “standard” I/O cells, which are predefined, generic interface units provided by semiconductor foundries or design companies that are intended for general purpose use across a variety of IC designs. A standard I/O cell in an IC generally has one pad that serves as the physical interface connecting signals from the core of the IC to the external environment. The pad is typically wired to an external pin on the IC package, allowing the chip to send signals to and receive signals from other devices or ICs.

As standard I/O cells typically have only one pad, a conventional approach in serial interface design is to use one standard I/O cell (clock I/O cell) to handle the clock signal that provides synchronization between the devices and another standard I/O cell (data I/O cell) to handle the serial bit stream conveyed from the target device to the initiator device. The use of one standard I/O cell to handle the clock signal and another standard I/O cell to handle the data signal, while versatile and providing broad compatibility between devices, presents significant limitations. In particular, the physical and logical separation between the data and clock paths leads to propagation delays from the clock signal input to the data signal output due to unnecessary and duplicated components such as level shifters and buffers, and added wire length and routing complexity associated with these components. In applications such as read path communication in HDDs, data exchange with serial flash memory (e.g., NOR flash memory), and any other application that requires a serial interface, any delay in signal transfer can significantly affect the performance of the overall system. The time-critical nature of these operations necessitates a more streamlined approach to the design of the serial interface.

The description provided in this background section should not be assumed to be prior art merely because it is mentioned in or associated with this background section. The background section may include information that describes aspects of this disclosure.

### SUMMARY

The following summary relates to one or more aspects or embodiments disclosed herein. It is not an extensive overview relating to all contemplated aspects or embodiments, and should not be regarded as identifying key or critical elements of all contemplated aspects or embodiments, or as delineating the scope associated with any particular aspect or embodiment. The following summary has the sole purpose of presenting certain concepts relating to one or more aspects or embodiments disclosed herein in a simplified form to precede the detailed description that follows.

This disclosure seeks to overcome the limitations of conventional serial interface design by combining data and clock signal functionalities into a single, integrated I/O cell having two (dual) pads: a clock pad for the clock signal and a data pad for the data signal. This approach minimizes propagation delays between the clock input and data output by eliminating unnecessary components such as level shifters and buffers and wire delays associated with these eliminated components. Further, the novel I/O cell architecture of this disclosure incorporates the flip-flop for controlling data output directly into the I/O cell and its I/O voltage domain and drives or triggers the flip-flop via a direct connection to the clock input buffer within the same I/O cell. In conventional architectures, by contrast, the flip-flop for controlling data output is located in the digital core voltage domain of the target device rather than in the serial interface. thereby introducing propagation delays due to the separation of the data and clock paths.

Accordingly, one aspect of this disclosure is a serial interface comprising an I/O cell configured to facilitate communication of serial data from a target device to an initiator device. The I/O cell comprises a clock pad configured to receive a clock signal from the initiator device; a data pad configured to receive a data output signal from control logic of the target device; a clock input buffer coupled to the clock pad and configured to receive the clock signal; a flip-flop coupled to the clock input buffer and configured to receive the clock signal directly from the clock input buffer, to receive the data output signal from the control logic of the target device, and to output the data output signal in synchronization with the clock signal; and a data output buffer coupled to the flip-flop, the data output buffer configured to receive the data output signal from the flip-flop and to drive the data output signal to the data pad for access by the initiator device.

In some implementations, the I/O cell further comprises a data output voltage level shifter configured to be coupled between the flip-flop and the control logic of the target device. The flip-flop is configured to operate in a first voltage domain and the control logic is configured to operate in a second voltage domain, and the data output voltage level shifter is configured to translate a voltage level of the data output signal from the second voltage domain to the first voltage domain.

In some implementations the first voltage domain is an I/O voltage domain from about 0V to about 1.8V, and the second voltage domain is a digital core voltage domain from about 0V to about 0.8V.

In some implementations, the I/O cell further comprises a clock voltage level shifter configured to be coupled between the clock input buffer and the control logic of the target device. The clock voltage level shifter is configured to translate a voltage level of the clock signal from the first voltage domain to the second voltage domain.

In some implementations, the I/O cell further comprises a data input buffer coupled to the data pad, wherein the data pad is further configured to receive a data input signal from the initiator device. A data input voltage level shifter is configured to be coupled between the data input buffer and the control logic of the target device and is configured to translate a voltage level of the data input signal from the first voltage domain to the second voltage domain.

In some implementations, the data output buffer and the data input buffer are tri-state buffers.

Another aspect of this disclosure is a circuit comprising a target device; an initiator device configured to read serial data from control logic of the target device in synchronization with a clock signal provided by the initiator device; and an I/O (input/output) cell configured to communicate the serial data from the control logic of the target device to the initiator device. The I/O cell comprises a clock pad configured to receive the clock signal from the initiator device; a data pad configured to receive a data output signal from the control logic of the target device; a clock input buffer coupled to the clock pad and configured to receive the clock signal; a flip-flop coupled to the clock input buffer and configured to receive the clock signal directly from the clock input buffer, to receive the data output signal from the control logic of the target device, and to output the data output signal in synchronization with the clock signal; and a data output buffer coupled to the flip-flop, the data output buffer configured to receive the data output signal from the flip-flop and drive the data output signal to the data pad for access by the initiator device.

In some implementations, the target device is a preamplifier of a hard disk drive (HDD) and the initiator device is a controller of the HDD. In other implementations, the target device is a serial flash memory. As such the various implementations may be within an HDD or other types of data storage device such as a flash memory based device.

A further aspect of this disclosure is a method for communicating serial data from control logic of a target device to an initiator device via an I/O (input/output) cell. The method comprises receiving, at a flip-flop of the I/O cell, a data output signal from the control logic of the target device; receiving a clock signal from the initiator device on a clock pad of the I/O cell; transmitting the clock signal from the clock pad to a clock input buffer of the I/O cell; transmitting the clock signal from the clock input buffer directly to the flip-flop of the I/O cell; transmitting the data output signal from the flip-flop to a data output buffer of the I/O cell in synchronization with the clock signal; and transmitting the data output signal from the data output buffer to a data pad of the I/O cell for access by the initiator device.

These and other aspects of this disclosure are described below and depicted in the accompanying drawings and will be further apparent based thereon.

### BRIEF DESCRIPTION OF THE DRAWINGS

Various features and advantages of this disclosure will be apparent from the following description and accompanying drawings. The drawings are not necessarily to scale; emphasis instead is placed on illustrating the principles of this disclosure. In the drawings, like reference characters may refer to the same parts throughout the different views. The drawings depict only illustrative examples of this disclosure and are not limiting in scope.

FIG. 1 is a conceptual circuit diagram showing a serial interface between an initiator device and a target device implemented by separate clock and data I/O cells, in accordance with aspects of this disclosure.

FIG. 2 is a conceptual circuit diagram showing a serial interface between an initiator device and a target device implemented by a single I/O cell having dual pads that provide both clock and data functionality, in accordance with aspects of this disclosure.

FIG. 3 is a flow diagram of a method for communicating serial data from a target device to an initiator device via an I/O cell, in accordance with aspects of this disclosure.

### DETAILED DESCRIPTION

The words “exemplary” and “example” as used herein mean “serving as an example, instance, or illustration.” Any embodiment described herein as “exemplary” or as an “example” should not be construed as preferred or advantageous over other embodiments.

The embodiments described herein do not limit the invention to the precise form disclosed, nor are they exhaustive. Rather, various embodiments are presented to provide a description for utilization by others skilled in the art. Technology continues to develop, and elements of the disclosed embodiments may be replaced by improved and enhanced items. This disclosure inherently discloses elements incorporating technology available at the time of this disclosure.

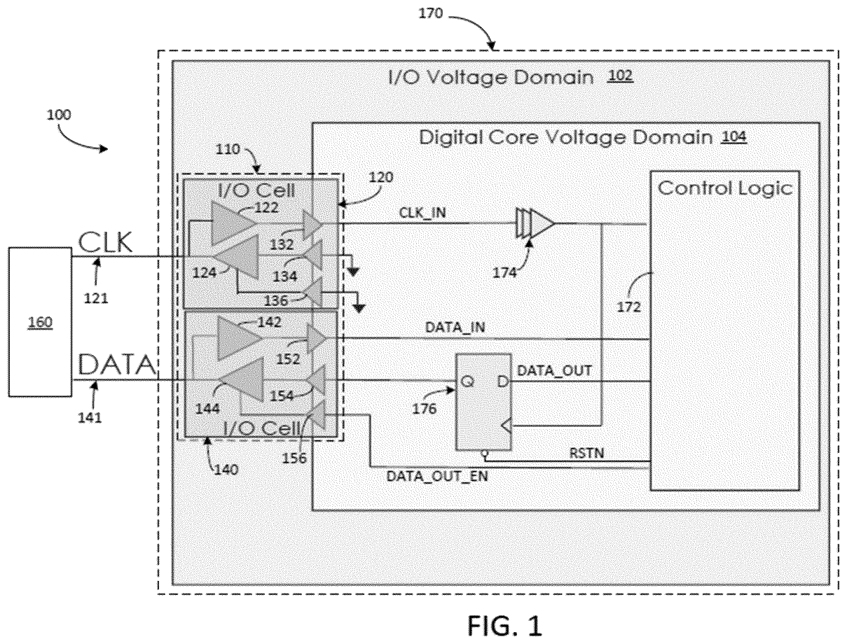

FIG. 1 is a conceptual circuit diagram 100 showing a serial I/O interface (SIO) 110 coupled between initiator device 160 and target device 170, in accordance with aspects of this disclosure. In some examples, as shown in FIG. 1, serial I/O interface 110 may be incorporated within target device 170. Initiator device 160 may be any system level clocking IC or system on a chip (SoC). Target device 170 may be any IC, application-specific IC (ASIC), or SoC that outputs or inputs a serial bit stream. In the non-limiting context of a hard disk drive (HDD), for example, target device 170 may be a preamplifier or PLSI that is connected to the read/write head and amplifies signals read from the disk surface, and initiator device 160 may be an HDD controller that manages overall HDD operations and the flow of data read from target device 170. In another non-limiting example, target device 170 may be a serial flash memory such as a NOR flash memory.

As can be seen in FIG. 1, serial interface 110 is implemented by two I/O cells: clock I/O cell 120 and data I/O cell 140. Typically, I/O cells 120 and 140 are selected from a library of “standard” I/O cells, which are predefined, generic interface units provided by semiconductor foundries or design companies that are intended for general purpose use across a variety of IC designs. A standard I/O cell may include, for example, an input buffer in a first (I/O) voltage domain, voltage level shifter(s) to translate a signal from the input buffer from the first voltage domain to a second (digital core) voltage domain; voltage level shifter(s) to translate a signal from the target device from the second (digital core) voltage domain to the first (I/O) voltage domain; and an output buffer in the first (I/O) voltage domain. A typical standard I/O cell has a single I/O pad that is connected to both the input buffer and the output buffer.

As standard I/O cells typically have only one I/O pad, a conventional approach in serial interface design is to use one standard I/O cell (e.g., clock I/O cell 120) to handle the clock signal that provides synchronization between the devices, and to use another standard I/O cell (e.g., data I/O cell 140) to handle the serial bit stream conveyed from the target device to the initiator device. In the example of FIG. 1, clock I/O cell 120 receives a clock signal from initiator device 160 on its single clock pad 121, and data I/O cell 140 transmits a data output signal from target device control logic 172 to initiator device 160 on its single data pad 141. As shown in FIG. 1, pads 121 and 141 may be wired to external pins to facilitate electrical coupling of serial interface 110 and initiator device 160.

Target device 170 comprises first (I/O) voltage domain 102 and second (digital core) voltage domain 104. Serial interface 110 operates in I/O voltage domain 102, and control logic 172, clock tree 174, and flip-flop 176 operate in digital core voltage domain 104. In the non-limiting context of an HDD, where target device 170 is a preamplifier or PLSI of an HDD and source device 160 is an HDD controller, I/O voltage domain 102 operates between about 0V and about 1.8V, and digital core voltage domain 104 operates between about 0V and about 0.8V. For other devices, voltage domains 102 and 104 may operate at different voltage levels. As will be explained below, serial interface 110 comprises voltage level shifters that translate between voltage domains 102 and 104.

Clock I/O cell 120 includes clock input buffer (or clock input receiver) 122 and clock voltage level shifter 132 in the input path, and output buffer (or output driver) 124 and voltage level shifters 134 and 136 in the output path. Similarly, data I/O cell 140 includes data input buffer (data input receiver) 142 and data input voltage level shifter 152 in the input path, and data output buffer (data output driver) 144 and voltage level shifters 152 and 154 in the output path. In the example of FIG. 1, initiator device 160 reads serial data via serial interface 110 from control logic 172 of target device 170. A clock signal is provided by initiator device 160 to clock I/O cell 120 to synchronize data communication and to drive control logic 172 of target device 170. Thus, in clock I/O cell 120, in a read data operation initiated by initiator device 160, only the components in the clock signal input path (clock input buffer 122 and clock voltage level shifter 132) are active. Similarly, in data I/O cell 140, as serial data is being read from control logic 172 of target device 170 by initiator device 160, only the components in the data output signal path (data output buffer 144 and voltage level shifters 154 and 156) are active.

Clock I/O cell 120 serves as the interface between an external clock source (here, initiator device 160) and the internal clock distribution network (clock tree 174) of target device 170. Clock I/O cell 120 translates the external clock signal (which operates in the I/O voltage domain; typically a higher voltage) to a compatible voltage level for clock tree 174 of target device 170 (which operates in the digital core voltage domain; typically a lower voltage). Clock input buffer 122 receives the clock signal from initiator device 160 via clock pad 121 and conditions the incoming clock signal to be at a suitable voltage level and strength for clock voltage level shifter 132. In some examples, clock input buffer 122 and output buffer 124 are tri-state buffers that can exist in a high voltage output (clock high) state, a low voltage output (clock low) state, or a high impedance (Z) state that is essentially an “off” state where the buffer is disconnected from the circuit. Thus, where first (I/O) voltage domain 102 operates between about OV and about 1.8V, clock input buffer 122 drives its output to a high voltage level (about 1.8V) when the input clock signal is high, and to a low voltage level (about 0V) when the input clock signal is low. Meanwhile, output buffer 124 may be set to the high impedance (Z) state to essentially disconnect it from the circuit, since no clock signal is output by clock I/O cell 120 to clock pad 121 in the illustrated configuration where data is read from target device 170 based on the clock signal of initiator device 160.

Clock voltage level shifter 132 transitions the voltage of the clock signal from the higher (I/O) voltage domain 102 of input clock buffer 122 to the lower (digital core) voltage domain 104 of control logic 172 and clock tree 174. This involves reducing the voltage while preserving the timing and sharpness of the clock signal. Where second (digital core) voltage domain 104 operates between about 0V and about 0.8V, for example, clock voltage level shifter 132 outputs a signal of about 0.8V when the clock signal is high and a signal of about OV when the clock signal is low.

Clock tree 174 of target device 170 receives the clock signal, now translated to be in second (digital core) voltage domain 104, and routes the clock signal to all components of target device 170 whose operations are to be timed based on the clock signal. Clock trees are fundamental elements in digital synchronous logic design. Clock tree 174 may comprise a vast network of flip-flops-potentially thousands-each operating on the same clock signal. All flip-flops sharing a common clock must be intricately placed and routed within the circuit layout to ensure that they receive the clock signal edge simultaneously. To achieve this, clock trees are often implemented as a series of digital buffers that can be visualized as a branching tree. The objective of the clock tree is synchronization: each flip-flop at the termini of these branches should receive the edge of the clock signal at precisely the same time to avoid timing discrepancies.

One of the termini in clock tree 174—flip-flop 176—is of particular importance to this disclosure as it is responsible for driving and controlling serial data output. For controlling serial data output, the clock signal is routed by clock tree 174 to flip-flop 176. The serial output data initiates in control logic 172. Flip-flop 176 temporarily stores a bit of the serial data output by control logic 172 in synchronization with the clock signal. On each clock pulse, a new bit is loaded into input D of flip-flop 176 from control logic 172, and the bit that was stored in flip-flop 176 is shifted out to output Q. The output Q of flip-flop 176 remains stable and retains its value until the next triggering clock pulse. Thus, data bits are output by flip-flop 176 in a serial stream at the correct times based on the clock signal provided by initiator device 160. Flip-flop 176 also receives a reset signal (RSTN) from control logic 172, such that control logic 172 can clear or initialize flip-flop 176 as needed.

After a data bit exits flip-flop 176, it enters data output voltage level shifter 154 of data I/O cell 140. Data output voltage level shifter 154 transitions the voltage of the data output signal from lower (digital core) voltage domain 104 of flip-flop 176 to higher (I/O) voltage domain 102 of data I/O cell 140. Where first (I/O) voltage domain 102 operates between about OV and about 1.8V, for example, data output voltage level shifter 154 outputs a signal of about 1.8V for a logical high bit (translated from 0.8V in digital core voltage domain 104) and a signal of about OV for a logical low bit. The translated data output signal then enters data output buffer (data output driver) 144, which may be configured as a tri-state buffer. Data output buffer 144 conditions the data output signal, which is then output to data pad 141 and is accessible by initiator device 160. Data output buffer 144 also receives a data out enable signal via voltage level shifter 156. The data out enable signal determines whether data output buffer 144 actively drives the data output signal to data pad 141 or is isolated from data pad 141 by switching to the high impedance (Z) state. Meanwhile, data input buffer 142 may be set to the high impedance (Z) state to essentially disconnect it from data pad 141, since no data input signal is received on data pad 141 from initiator device 160 in the illustrated configuration where data is read from (not written to) target device 170.

The signal propagation delay in the read path from receiving a clock input signal on clock pad 121 to transmitting a data output signal to data pad 141 is a fundamental limitation on the maximum speed of serial interface 110 in reading data from control logic 172 of target device 170. As shown in FIG. 1, the read path typically includes additive delays associated with signal propagation through clock input buffer 122; clock voltage level shifter 132; the digital buffers of clock tree 174; flip-flop 176; data output voltage level shifter 154; data output buffer 144; and the wiring associated with the buffers and volage level shifters in the read path. The total of the delays in the read path determines the maximum clock frequency. In the non-limiting context of an HDD, for example, for a clock signal having a frequency of 200 MHz, there may be about an 8.3 ns timing budget for the read path. This may include about a 2 ns budget for the SoC controller (i.e., initiator device 160), a 3.6 ns budget for PCB (printed circuit board) and transition time, and a 2.7 ns budget for target device internal delays from clock pad 121 to data pad 141 (i.e., signal propagation through input clock buffer 122; clock voltage level shifter 132; the digital buffers of clock tree 174; flip-flop 176; data output voltage level shifter 154; data output buffer 144; and the wiring associated with these components. In applications such as read path communication in HDDs, data exchange with serial flash memory, and other applications that require a serial interface, signal propagation delays such as those described above can significantly affect the performance of the overall system and limit the maximum clock frequency.

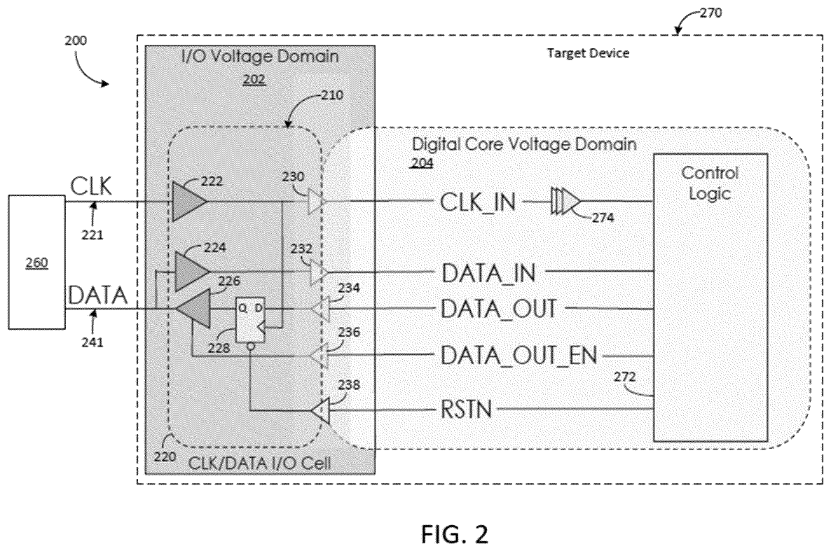

FIG. 2 is a conceptual circuit diagram 200 showing a serial I/O interface (SIO) 210 coupled between initiator device 260 and target device 270, in accordance with aspects of this disclosure. In some examples, as shown in FIG. 2, serial I/O interface 210 may be incorporated within target device 270. Serial I/O interface 210 advantageously minimizes the overall delay associated with components in the read path so that the clock frequency can be increased and the timing budget attributable to serial I/O interface 210 can be reduced. According to aspects of this disclosure, signal propagation delays associated with serial interface designs such as serial interface 110 of FIG. 1 are reduced by combining data and clock signal functionalities into a single, integrated I/O cell 220 having two (dual) pads: clock pad 221 for the clock signal and data pad 241 for the data signal. This approach minimizes propagation delays between the clock input and data output by eliminating unnecessary components such as level shifters and buffers and wire delays associated with these eliminated components.

In addition, the novel architecture of I/O cell 220 incorporates a flip-flop 228 for controlling data output directly into I/O cell 220. Flip-flop 228 is synchronized or driven via a direct connection to input clock buffer 224 within the same I/O cell 220 and operates in first (I/O) voltage domain 202 of target device 270. In the configuration of FIG. 1, by contrast, flip-flop 176 for controlling data output is located in second (digital core) voltage domain 104 of target device 170 and not in first (I/O) voltage domain 102, thereby introducing propagation delays due to the separation of the data and clock paths and the need for additional voltage level shifters and buffers.

As can be seen in FIG. 2, serial interface 210 is implemented by a single, custom I/O cell 220 having two pads 221, 241 that integrate clock and data functionality. In contrast to I/O cells 120 and 140 of serial interface 110 of FIG. 1, I/O cell 220 is designed and customized as described herein and is not selected from a library of standard single pad I/O cells. In the example of FIG. 2, I/O cell 220 receives a clock signal from initiator device 260 on clock pad 221, and transmits a data output signal from control logic 272 of target device 270 to initiator device 260 on data pad 241. Pads 221 and 241 may be wired to external pins to facilitate electrical coupling of serial interface 210 and initiator device 260. Initiator device 260 may be any system level clocking IC or system on a chip (SoC). Target device 270 may be any IC, application-specific IC (ASIC), or SoC that outputs or inputs a serial bit stream. In the non-limiting context of a hard disk drive (HDD), for example, target device 270 may be a preamplifier or PLSI that is connected to the read/write head and amplifies signals read from the disk surface, and initiator device 260 may be an HDD controller that manages overall HDD operations and the flow of data read from target device 270. In another non-limiting example, target device 270 may be a serial flash memory such as a NOR flash memory.

Target device 270 comprises first (I/O) voltage domain 202 and second (digital core) voltage domain 204. Serial interface 210 operates in first (I/O) voltage domain 202, and control logic 272 and clock tree 274 operate in second (digital core) voltage domain 204. In the non-limiting context of an HDD, where target device 270 is a preamp or PLSI of an HDD and initiator device 260 is an HDD controller, first (I/O) voltage domain 202 operates between about OV and about 1.8V, and second (digital core) voltage domain 204 operates between about OV and about 0.8V. For other devices, voltage domains 202 and 204 may operate at different voltage levels. Serial interface 210 comprises voltage level shifters that translate between voltage domains 202 and 204.

I/O cell 220 includes clock input buffer (clock input receiver) 222 and clock voltage level shifter 230 in the input path from clock pad 221, and data output buffer (data output driver) 226, flip-flop 228, and data output voltage level shifter 234 in the output path to data pad 241. I/O cell 220 also includes data input buffer 224 and data input voltage level shifter 232 in the input path from data pad 241. In the example of FIG. 2, initiator device 260 reads serial data via serial interface 210 from control logic 272 of target device 270, and a clock signal is provided by initiator device 260 to I/O cell 220 to synchronize data communication and to drive control logic 272 of target device 270. Thus, as serial data is read from target device 270 by initiator device 260, only components in the data output signal path (data output buffer 226, flip-flop 228, and data output voltage level shifter 234) are active.

Advantageously, flip-flop 228 is powered in first (I/O) voltage domain 202 and is driven directly by clock input buffer 222, without any intervening voltage level shifters. In comparison to serial interface 110 of FIG. 1, the propagation delays of the clock signal through clock voltage level shifter 132, and then through the digital buffers of clock tree 174, and the wire delays associated with these elements, are reduced or substantially eliminated. Moreover, whereas flip-flop 176 of FIG. 1 is powered in second (digital core) voltage domain 104, flip-flop 228 of serial interface 220 of FIG. 2 is powered in first (I/O) voltage domain 202. Thus, for serial data communication, flip-flop 228 is directly clocked in I/O voltage domain 202 without associated propagation delays through voltage level shifters and a clock tree, thereby allowing an increase in the clock frequency and a corresponding increase in the serial data output speed of serial interface 210.

With the exception of flip-flop 228, which is now incorporated directly into I/O cell 220 and tied directly to the clock signal output by clock input buffer 222 to control serial data output, I/O cell 220 continues to serve as an interface between the external clock source (initiator device 260) and the internal clock distribution network (clock tree 274) of target device 270. I/O cell 220 translates the external clock signal (which operates in I/O voltage domain; typically a higher voltage) to a compatible voltage level for clock tree 274 of target device 270 (which operates in the digital core voltage domain, typically a lower voltage). Clock input buffer 222 receives the clock signal on clock pad 221 from initiator device 260 and conditions the incoming clock signal to be at a suitable voltage level and strength for clock voltage level shifter 230 (and flip-flop 228). In some examples, clock input buffer 222, data output buffer 226, and data input buffer 224 are tri-state buffers that can exist in a high voltage output (clock high) state, a low voltage output (clock low) state, or a high impedance (Z) state that is essentially an “off” state where the buffer is disconnected from the circuit. Thus, where first (I/O) voltage domain 202 operates between about 0V and about 1.8V, clock input buffer 222 drives its output to a high voltage level (about 1.8V) when the input clock signal is high, and to a low voltage level (about 0V) when the input clock signal is low.

Clock voltage level shifter 230 transitions the voltage of the clock signal from the higher (I/O) voltage domain 202 of clock input buffer 222 to the lower (digital core) voltage domain 204 of control logic 272 and clock tree 274. This involves reducing the voltage while preserving the timing and sharpness of the clock signal. Where second (digital core) voltage domain 204 operates between about 0V and about 0.8V, for example, clock voltage level shifter 230 outputs a signal of about 0.8V when the clock signal is high and a signal of about OV when the clock signal is low.

Clock tree 274 of target device 270 receives the clock signal, now translated to be in second (digital core) voltage domain 204, and routes the clock signal to components of target device 270 (other than flip-flop 228) whose operations are to be timed based on the clock signal. As mentioned above, clock trees are fundamental elements in digital synchronous logic design that are often implemented as a series of digital buffers. According to this disclosure, since flip-flop 228 is directly driven by clock input buffer 222 in I/O voltage domain 202, the propagation delays imposed by clock voltage level shifter 230 and the digital buffers of clock tree 274 are minimized or eliminated for serial data communication.

Output data initiates in control logic 272, and is transmitted to flip-flop 228 in I/O cell 220 via data output voltage level shifter 234. Data output voltage level shifter 234 transitions the voltage of the data output signal from the lower voltage domain 204 of control logic 272 to the higher voltage domain 202 of I/O cell 220. Where first (I/O) voltage domain 202 operates between about 0V and about 1.8V, for example, data output voltage level shifter 234 outputs a signal of about 1.8V for a logical high bit (translated from about 0.8V in digital core voltage domain 204) and a signal of about 0V for a logical low bit.

Flip-flop 228 temporarily stores a bit of the serial data stream output by control logic 272 and voltage level shifter 234 in synchronization with the clock signal provided by clock input buffer 222 of I/O cell 220. On each clock pulse, a new bit is loaded into input D of flip-flop 228 from control logic 272, and the bit that was stored in flip-flop 228 is shifted out to output Q. Output Q of flip-flop 228 remains stable and retains its value until the next triggering clock pulse. Thus, data bits are output by flip-flop 228 as a serial bit stream at the correct times based on the clock signal provided by initiator device 260 via clock input buffer 222. Flip-flop 228 also receives a reset signal (RSTN) from control logic 272, via voltage level shifter 238, such that control logic 272 can clear or initialize flip-flop 228 as needed.

After a data bit exits flip-flop 228, it then enters data output buffer 226, which may be configured as a tri-state buffer. Data output buffer 226 conditions the data signal, which is then output to data pad 241 and is accessible by initiator device 260. Data output buffer 226 also receives a data out enable signal via voltage level shifter 236. The data out enable signal determines whether data output buffer 226 actively drives the data output signal to pad 241 or is isolated from the circuit by switching to the high impedance (Z) state. Meanwhile, data input buffer 224 may be set to the high impedance (Z) state to essentially disconnect it from data pad 241, since no data signal is received on data pad 241 from initiator device 260 in the illustrated configuration where data is read from (not written to) target device 270.

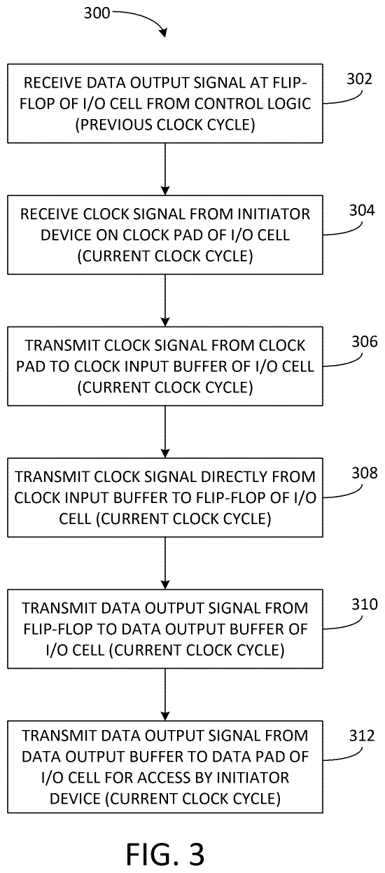

FIG. 3 illustrates a method 300 for communicating serial data from control logic 272 of target device 270 to initiator device 260 via I/O cell 220, in accordance with this disclosure. In step 302 of method 300, in the previous clock cycle, an output data signal is received by flip-flop 228 of I/O cell 220 from control logic 272. In some examples, step 302 comprises receiving the data output signal from control logic 272 at data output voltage level shifter 234, which translates a voltage level of the data output signal from second (digital core) voltage domain 204 to first (I/O) voltage domain 202, and then transmits the data output signal to flip-flop 228.

In step 304, in the current clock cycle, a clock signal is received from initiator device 260 on clock pad 221 of I/O cell 220. In step 306, in the current clock cycle, the clock signal is transmitted from clock pad 221 to clock input buffer 222 of I/O cell 220. In step 308, in the current clock cycle, the clock signal is transmitted from clock input buffer 222 directly to flip-flop 228 of I/O cell 220. The clock signal is also transmitted from clock input buffer 222 to clock voltage level shifter 230 of I/O cell 220. Clock voltage level shifter 230 translates a voltage level of the clock signal from first (I/O) voltage domain 202 of I/O cell 220 to second (digital core) voltage domain 204 of control logic 272 and clock tree 274, and transmits the clock signal to clock tree 274 for further distribution. In step 310, in the current clock cycle, the data output signal is transmitted from flip-flop 228 to data output buffer 226 of I/O cell 220 in synchronization with the clock signal. In step 312, in the current clock cycle, the data output signal is transmitted from data output buffer 226 to data pad 241 of I/O cell 220 for access by initiator device 260.

As noted above, In the non-limiting context of an HDD, for a clock signal having a frequency of 200 MHz, there may be about an 8.3 ns timing budget for the read path. This may include about a 2 ns budget for the SoC controller (i.e., initiator device 160), a 3.6 ns budget for PCB (printed circuit board) and transition time, and a 2.7 ns budget for target device internal delays from clock pad 121 to data pad 141. In traditional SOCs, such as target device 170 of FIG. 1, the total target device internal delay includes signal propagation through input clock buffer 122; clock voltage level shifter 132; the digital buffers of clock tree 174; flip-flop 176; data output voltage level shifter 154; data output buffer 144; and the wiring associated with these components. By contrast, in the proposed SOC of this disclosure, such as target device 270 of FIG. 2, the total target device internal delay is reduced and comprises only signal propagation through clock input buffer 222; flip-flop 228; and data output buffer 226. Thus, the total internal delay for the proposed SOC (e.g., target device 270 of FIG. 2) is substantially shorter than the total internal delay for a traditional SOC (e.g., target device 170 of FIG. 1), thereby allowing the 2.7 ns budget for target device internal delays to be achieved more easily and providing a margin for increasing the clock frequency of the serial interface.

In some examples, method 300 is implemented by suitable control circuitry of I/O cell 220, initiator device 260, and/or target device 270, which in turn may be implemented in one or more components of an HDD. Method 300 may be implemented by a microprocessor executing instructions that cause the microprocessor to perform the flow diagram of FIG. 3. The instructions may be stored in any computer-readable medium. In some examples, the instructions may be stored on a non-volatile semiconductor memory device, component, or system external to the microprocessor, or integrated with the microprocessor in an SoC.

While certain embodiments are described herein, these embodiments are presented by way of example only, and do not limit the scope of this disclosure. Various omissions, substitutions and changes may be made without departing from the spirit and scope of this disclosure. The methods and processes described herein are not limited to any particular sequence and may be used independently or combined in various ways. Some method or process steps may be omitted and other steps added in some implementations. Nothing in this description implies that any particular feature, component, characteristic, or step is necessary or indispensable. Many variations, modifications, additions, and improvements are possible and fall within the scope of this disclosure as defined by the following claims.

What is claimed is:

1. A serial interface comprising an I/O (input/output) cell configured to facilitate communication of serial data from a target device to an initiator device, the I/O cell comprising:
a clock pad configured to receive a clock signal from the initiator device;
a data pad configured to receive a data output signal from control logic of the target device;
a clock input buffer coupled to the clock pad and configured to receive the clock signal;
a flip-flop coupled to the clock input buffer and configured to:
receive the clock signal from the clock input buffer,
receive the data output signal from the control logic of the target device, and
output the data output signal in synchronization with the clock signal; and
a data output buffer coupled to the flip-flop, the data output buffer configured to receive the data output signal output by the flip-flop and to drive the data output signal to the data pad for access by the initiator device.

2. The serial interface of claim 1, wherein the I/O cell further comprises:
a data output voltage level shifter configured to be coupled between the flip-flop and the control logic of the target device, wherein
the flip-flop is configured to operate in a first voltage domain and the control logic is configured to operate in a second voltage domain, and
the data output voltage level shifter is configured to translate a voltage level of the data output signal from the second voltage domain to the first voltage domain.

3. The serial interface of claim 2, wherein the first voltage domain from about 0V to about 1.8V and the second voltage domain is from about 0V to about 0.8V.

4. The serial interface of claim 2, wherein the I/O cell further comprises:
a clock voltage level shifter configured to be coupled between the clock input buffer and the control logic of the target device,
wherein the clock voltage level shifter is configured to translate a voltage level of the clock signal from the first voltage domain to the second voltage domain.

5. The serial interface of claim 4, wherein the I/O cell further comprises:
a data input buffer coupled to the data pad, wherein the data pad is further configured to receive a data input signal from the initiator device; and
a data input voltage level shifter configured to be coupled between the data input buffer and the control logic of the target device,
wherein the data input voltage level shifter is configured to translate a voltage level of the data input signal from the first voltage domain to the second voltage domain.

6. The serial interface of claim 5, wherein the data output buffer and the data input buffer are tri-state buffers.

7. A data storage device comprising the serial interface of claim 1.

8. A circuit comprising:
a target device;
an initiator device configured to read serial data from control logic of the target device in synchronization with a clock signal provided by the initiator device; and
an I/O (input/output) cell configured to communicate the serial data from the control logic of the target device to the initiator device, the I/O cell comprising:
a clock pad configured to receive the clock signal from the initiator device;
a data pad configured to receive a data output signal from the control logic of the target device;
a clock input buffer coupled to the clock pad and configured to receive the clock signal;
a flip-flop coupled to the clock input buffer and configured to:
receive the clock signal from the clock input buffer,
receive the data output signal from the control logic of the target device, and
output the data output signal in synchronization with the clock signal; and
a data output buffer coupled to the flip-flop, the data output buffer configured to receive the data output signal from the flip-flop and drive the data output signal to the data pad for access by the initiator device.

9. The circuit of claim 8, wherein the target device is a preamplifier of a hard disk drive (HDD) and the initiator device is a controller of the HDD.

10. A hard disk drive (HDD) comprising the circuit of claim 9.

11. The circuit of claim 8, wherein the target device is a serial flash memory.

12. The circuit of claim 8, wherein the I/O cell further comprises:
a data output voltage level shifter coupled between the flip-flop and the control logic of the target device,
wherein the flip-flop is configured to operate in a first voltage domain and the control logic is configured to operate in a second voltage domain, and
wherein the data output voltage level shifter is configured to translate a voltage level of the data output signal from the second voltage domain to the first voltage domain.

13. The circuit of claim 12, wherein the I/O cell further comprises:
a clock voltage level shifter coupled between the clock input buffer and the control logic of the target device and configured to translate a voltage level of the clock signal from the first voltage domain to the second voltage domain.

14. The circuit of claim 13, wherein the I/O cell further comprises:
a data input buffer coupled to the data pad, wherein the data pad is further configured to receive a data input signal from the initiator device; and
a data input voltage level shifter coupled between the data input buffer and the control logic of the target device,
wherein the data input voltage level shifter is configured to translate a voltage level of the data input signal from the first voltage domain to the second voltage domain.

15. The circuit of claim 14, wherein the data output buffer and the data input buffer are tri-state buffers.

16. A data storage device comprising the circuit of claim 8.

17. A method for communicating serial data from control logic of a target device to an initiator device via an I/O (input/output) cell, the method comprising:
receiving, at a flip-flop of the I/O cell, a data output signal from the control logic of the target device;
receiving a clock signal from the initiator device on a clock pad of the I/O cell;
transmitting the clock signal from the clock pad to a clock input buffer of the I/O cell;
transmitting the clock signal from the clock input buffer directly to the flip-flop of the I/O cell;
transmitting the data output signal from the flip-flop to a data output buffer of the I/O cell in synchronization with the clock signal; and
transmitting the data output signal from the data output buffer to a data pad of the I/O cell for access by the initiator device.

18. The method of claim 17, further comprising:
receiving, at a data output voltage level shifter of the I/O cell, the data output signal from the control logic of the target device;
translating, with the data output voltage level shifter, a voltage level of the data output signal from a second voltage domain of the control logic to a first voltage domain of the flip-flop; and
transmitting the data output signal from the data output voltage level shifter to the flip-flop.

19. The method of claim 18, wherein the first voltage domain is an I/O voltage domain from about 0V to about 1.8V, and the second voltage domain is a digital core voltage domain from about 0V to about 0.8V.

20. The method of claim 18, further comprising:
receiving, at a clock voltage level shifter of the I/O cell, the clock signal from the clock input buffer;
translating, with the clock voltage level shifter, a voltage level of the clock signal from the first voltage domain to the second voltage domain; and
transmitting the clock signal from the clock voltage level shifter to a clock tree of the target device.
